(19) United States
(12) Patent Application Publication
(10) Pub. No.: US 2026/0143699 A1
(43) Pub. Date: May 21, 2026

(54) 3D STACKABLE SYNAPSE STRING AND 3D STACKABLE SYNAPSE ARRAY USING THE STRING

(71) Applicant: Seoul National University R&DB FOUNDATION, Seoul (KR)

(72) Inventors: Jong-Ho LEE, Seoul (KR); Young-tak SEO, Seongnam-si (KR); Soochang LEE, Seoul (KR); Seongbin OH, Seoul (KR); Jangsaeng KIM, Seoul (KR)

(21) Appl. No.: 19/444,169

(22) Filed: Jan. 8, 2026

Related U.S. Application Data
(63) Continuation-in-part of application No. 17/888,775, filed on Aug. 16, 2022.
(60) Provisional application No. 63/233,939, filed on Aug. 17, 2021.

(51) Int. Cl. H10B 41/41; G06N 3/063; H10B 41/20; H10B 63/00; H10B 63/10; H10B 80/00

(52) U.S. Cl. CPC H10B 41/41; G06N 3/063; H10B 41/20; H10B 63/10; H10B 63/84; H10B 80/00

(57) ABSTRACT

Provided is a 3D stackable synapse string. The 3D stackable synapse string includes: a channel hole having a pillar shape extending in a vertical direction and filled with an insulating material; a first synapse string provided on a first surface of an outer peripheral surface of the channel hole, the first synapse string including a plurality of first synapse devices stacked along a vertical direction of the channel hole; a second synapse string provided on a second surface of the outer peripheral surface of the channel hole, the second synapse string including a plurality of second synapse devices stacked along the vertical direction of the channel hole; and a device isolation portion provided on the outer peripheral surface of the channel hole between the first and second synapse strings. The two synapse strings are electrically separated from each other by the device isolation portion.

### TECHNICAL FIELD

The present invention relates to a three-dimensional stackable synapse string, a three-dimensional stackable synapse array using the same, and a method for manufacturing the three-dimensional stackable synapse string, and more specifically, to a three-dimensional stackable synapse array capable of improving the degree of integration and improving operational reliability by implementing a NAND-type synapse array in a three-dimensional stackable form and a method for manufacturing the same.

### BACKGROUND ART

In recent years, many approaches have been made to imitate nervous systems of animals as power consumption has increased significantly and heat release problems have become more serious in integrated circuits based on the von Neumann architecture. Particularly, in the techniques imitating the nervous systems of animals, it is possible to improve the cognitive function and the determining function by enabling cognitive function and learning while greatly reducing power consumption. As a result, there is an opportunity to replace or greatly improve the functionality of the existing von Neumann integrated circuits. Therefore, much attention has been increasingly paid to the techniques, and the need for research has been greatly increased.

The basic function of neurons is to generate electrical spikes and transmit information to other cells in a case where a stimulus exceeds a threshold value. The resulting electrical signal is called an action potential. Neurons may be roughly divided into three portions. The neuron includes a nerve cell body where a nucleus exists, a dendrite which receives a signal from another cell, and an axon which transmits a signal to another cell. A portion which transmits a signal between the dendrites is called a synapse.

The neuron receives a stimulus from another nerve cell or a stimulus receptor cell and transmits the stimulus to another nerve cell or a glandular cell. Exchanging the stimulus occurs at the synapse. One nerve cell (neuron) receives stimuli through a number of synapses and integrates the excitations, and after that, the nerve cell transmits an electrical spike to an axon near to the nerve cell body, so that the electrical spike reaches the synapse. In this manner, the transmission of the excitations from the neuron through the synapses to another nerve cell is referred to as excitation transmission. The excitation at the synapse is transmitted only from a nerve fiber toward a nerve cell body or a dendrite and is not transmitted in the reverse direction, so that the excitation is transmitted in only one direction as a whole. In addition, the synapses are not only relay sites that transmit the excitations but the synapses also cause weighting or inhibition according to temporal or spatial change in excitations reaching the synapses to enable higher level integration of the nervous system.

On the other hand, besides the synapses having the action of transmitting the excitation, there are synapses having the action of inhibiting the transmission of the excitations from other nerve cells. These synapses are called inhibitory synapses. When the excitation transmitted along some nerve fibers reaches the inhibitory synapse, the inhibitory transmitting material is secreted from the synapse. This inhibitory transmitting material acts on a cell membrane of the nerve cell connected to the synapse to inhibit the excitations of the cell from occurring (occurrence of an action potential). As a result, while the inhibitory transmitting material acts, the excitation reaching other synapses is not transmitted to the synapse.

Recently, various studies have been conducted to implement neural networks using RRAM devices (Xiaoyu Sun et al., “XNOR-RRAM: A Scalable and Parallel Resistive Synapse Architecture for Binary Neural Networks”, 2018 Design, Automation & Test in Europe Conference & Exhibition). However, in the case of Memristor-based synapses of the prior art, there is a disadvantage in that the reliability of the device is not good and the dispersion between the devices is large.

Also, recent attempts have been made to implement neural networks using SRAM devices (Si, X., et al., “A twin-8T SRAM computation-in-memory macro for multiple-bit CNN-based machine learning” In 2019 IEEE International Solid-State Circuits Conference-(ISSCC), pp. 396-398) However, implementing a neural network using an SRAM device according to the above-described prior art has good reliability, but has a disadvantage of low integration by using multiple devices.

Therefore, the present invention provides three-dimensional stackable synapse array architectures that can operate with low power and high reliability while increasing the degree of integration.

### SUMMARY OF THE INVENTION

In order to solve the problems of the prior art described above, an object of the present invention is to provide a three-dimensional stackable synapse string that can be implemented as a NAND-type synapse array, and has an excellent degree of integration and improved reliability.

Another object of the present invention is to provide a three-dimensional stackable synapse array using the three-dimensional stakable synapse string.

Another object of the present invention is to provide a method for manufacturing the three-dimensional stakable synapse string.

In the first aspect of the present invention, a three-dimensional stackable synapse string may comprise: a channel hole having a pillar shape extending in a vertical direction and being filled with an insulating material; a first synapse string provided on a first surface of an outer peripheral surface of the channel hole, the first synapse string including a plurality of first synapse devices stacked along a vertical direction of the channel hole; a second synapse string provided on a second surface of the outer peripheral surface of the channel hole, the second synapse string including a plurality of second synapse devices stacked along the vertical direction of the channel hole; and a device isolation portion provided on the outer peripheral surface of the channel hole between the first and the second synapse strings, wherein the three-dimensional stackable synapse string is configured to include two synapse strings electrically separated from each other by the device isolation portion on the outer peripheral surface of the channel hole.

In the three-dimensional stackable synapse string according to the first aspect of the present invention, it is preferable that each of the first synapse devices of the first synapse string comprises: a first semiconductor body provided in a thin-film form on the first surface of the outer peripheral surface of the channel hole; a first word line positioned on an outer peripheral surface of the first semiconductor body; and a first insulator stack positioned between the first word line and the first semiconductor body, wherein the first word lines of the first synapse string are electrically separated from each other, and the first synapse devices are electrically connected to each other by the first semiconductor body to form the first synapse string, and wherein each of the second synapse devices of the second synapse string comprises: a second semiconductor body provided in a thin-film form on the second surface of the outer peripheral surface of the channel hole; a second word line positioned on an outer peripheral surface of the second semiconductor body; and a second insulator stack positioned between the second word line and the second semiconductor body, wherein the second word lines of the second synapse string are electrically separated from each other, and the second synapse devices are electrically connected to each other by the second semiconductor body to form the second synapse string.

In the three-dimensional stackable synapse string according to the first aspect of the present invention, it is preferable that the device isolation portion comprises: a third semiconductor body provided in a thin-film form between the first surface and the second surface on the outer peripheral surface of the channel hole; a plurality of third insulating layers arranged along a vertical direction on an outer peripheral surface of the third semiconductor body; and a plurality of fourth insulating layers arranged along the vertical direction on the outer peripheral surface of the third semiconductor body and alternately stacked with the third insulating layers, wherein the device isolation portion electrically isolates the first synapse string from the second synapse string.

In the three-dimensional stackable synapse string according to the first aspect of the present invention, it is further preferable that the first, second, and third semiconductor bodies have the same structure and are made of the same material.

In the three-dimensional stackable synapse string according to the first aspect of the present invention, it is further preferable that the first and the second semiconductor bodies are connected to each other with the third semiconductor body interposed therebetween.

In the three-dimensional stackable synapse string according to the first aspect of the present invention, it is preferable that regions of the surface of the channel hole on which the first synapse devices and the second synapse devices are provided protrude toward the first word lines and the second word lines, respectively.

In the three-dimensional stackable synapse string according to the first aspect of the present invention, it is preferable that the first insulator stack and the second insulator stack are each configured as a single insulating layer or as a stack structure including a plurality of stacked layers, and wherein, in the stack structure, each of the first insulator stack and the second insulator stack includes at least a charge storage layer and an insulating layer, or at least a ferroelectric layer and an insulating layer, or at least a resistive switching layer and an insulating layer, or at least a phase change layer and an insulating layer.

In the three-dimensional stackable synapse string according to the first aspect of the present invention, it is preferable that the first insulator stack and the second insulator stack have the same structure and are made of the same material.

In the three-dimensional stackable synapse string according to the first aspect of the present invention, the three-dimensional stackable synapse string may further comprise: a first upper electrode disposed above the channel hole and electrically connected to a first end of the first synapse string; a first lower electrode disposed below the channel hole and electrically connected to a second end of the first synapse string; a second upper electrode disposed above the channel hole and electrically connected to a first end of the second synapse string; and a second lower electrode disposed below the channel hole and electrically connected to a second end of the second synapse string.

In the three-dimensional stackable synapse string according to the first aspect of the present invention, it is further preferable that the first synapse string and the second synapse string share the first upper electrode and the second upper electrode with each other, and share the first lower electrode and the second lower electrode with each other.

In the three-dimensional stackable synapse string according to the first aspect of the present invention, it is further preferable that the first synapse string and the second synapse string share the first upper electrode and the second upper electrode, and do not share the first lower electrode and the second lower electrode.

In the three-dimensional stackable synapse string according to the first aspect of the present invention, it is preferable that the three-dimensional stackable synapse string is provided on a substrate having an oxide layer on a surface thereof, wherein the first lower electrode is disposed between the second end of the first synapse string and an upper surface of the oxide layer of the substrate, and wherein the second lower electrode is disposed between the second end of the second synapse string and the upper surface of the oxide layer of the substrate.

In the second aspect of the present invention, a three-dimensional stackable synapse array may comprise a plurality of the three-dimensional stackable synapse strings, each according to the first aspect, arranged in an array form.

In some embodiments, the three-dimensional stackable synapse array may further comprise a CMOS integrated circuit used as a peripheral circuit below a substrate on which the three-dimensional stackable synapse array is formed.

### BRIEF DESCRIPTION OF THE DRAWINGS

FIG. 1 is a perspective view showing a three-dimensional stackable synapse string according to a preferred embodiment of the present invention, FIG. 2 is a cross-sectional view taken along the A-A direction of FIG. 1, FIG. 3A is a cross-sectional view taken in the first direction of FIG. 2, and FIG. 3B is a cross-sectional view taken in the second direction of FIG. 2.

FIG. 4 is a flowchart sequentially illustrating a method for manufacturing the three-dimensional stackable synapse string according to the preferred embodiment of the present invention shown in FIG. 3, and FIGS. 5A and 5B are cross-sectional views and top views showing the results of each step of FIG. 4.

FIGS. 6A and 6B are cross-sectional views in first and second directions illustrating another embodiment of a channel hole in the three-dimensional stackable synapse string according to the preferred embodiment of the present invention.

FIG. 7 is cross-sectional views and top views showing the results of some steps in the manufacturing method of the three-dimensional stackable synapse string of the present invention shown in FIG. 6.

FIG. 8 is a perspective view showing another embodiment of a second electrode in the three-dimensional stackable synapse string according to the preferred embodiment of the present invention, FIG. 9 is a cross-sectional view taken along the A-A direction of FIG. 8, FIG. 10A is a cross-sectional view taken in the first direction of FIG. 9, and FIG. 10B is a cross-sectional view taken in the second direction of FIG. 9.

FIG. 11 is cross-sectional views and Top Views showing the results of some steps in the manufacturing method of the three-dimensional stackable synapse string of the present invention shown in FIG. 8.

FIGS. 12 and 13 are a cross-sectional view and an equivalent circuit diagram illustrating an example of a NAND-type synapse array structure configured using three-dimensional stackable synapse arrays using the three-dimensional stackable synapse string according to the present invention.

FIG. 14 is a schematic diagram illustrating the degree of integration in the three-dimensional stackable synapse string according to the present invention.

FIGS. 15A and 15B are an equivalent circuit diagram and a table showing voltages applied to each terminal for explaining a selective program operation for a target device in the three-dimensional stackable synapse array according to the present invention.

FIGS. 16A and 16B are graphs of read results for a synapse device (CELL A) that has performed a selective program operation and a synapse device (CELL B) that does not perform a selective program operation according to the selective program operation according to FIGS. 15A and 15B.

FIGS. 17A and 17B are an equivalent circuit diagram and a table showing voltages applied to each terminal for explaining a selective erase operation for a target device in the three-dimensional stackable synapse array structure shown in FIG. 16.

FIGS. 18A and 18B are graphs of read results for a synapse device (CELL A) that has performed a selective program operation and a synapse device (CELL B) that does not perform a selective program operation according to the selective program operation according to FIG. 17.

### DETAILED DESCRIPTION

Hereinafter, the three-dimensional stackable synapse string made of synapse devices according to the present invention, the three-dimensional stackable synapse array using the three-dimensional stackable synapse string, and a manufacturing method thereof will be described in detail with reference to the accompanying drawings.

### 3D Stackable Synapse String

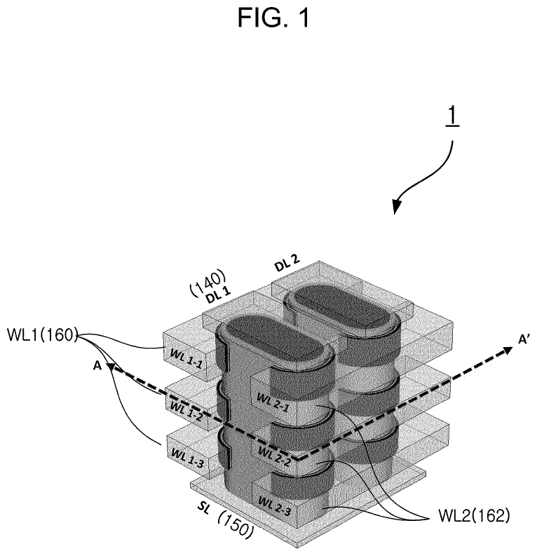

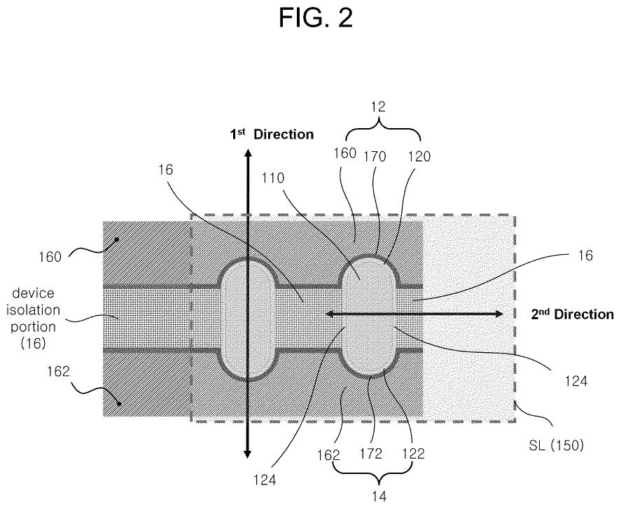

FIG. 1 is a perspective view showing the three-dimensional stackable synapse string according to the preferred embodiment of the present invention, FIG. 2 is a cross-sectional view taken along the A-A direction of FIG. 1, FIG. 3A is a cross-sectional view taken in the first direction of FIG. 2, and FIG. 3B is a cross-sectional view taken in the second direction of FIG. 2.

Hereinafter, with reference to FIGS. 1 to 3, the structure and operation of the three-dimensional stackable synapse string according to the preferred embodiment of the present invention will be described in detail. For convenience, in the present specification, the three-dimensional stackable synapse string is described assuming that the cell devices have a stacked structure of three layers. However, the three-dimensional stackable synapse string according to the present invention is not limited to the three-layer stacked structure of the cell devices, and may be manufactured as a stacked structure consisting of a plurality of more layers if necessary.

Referring to FIGS. 1 to 3, the three-dimensional stackable synapse string 1 according to the preferred embodiment of the present invention includes a channel hole 110, a first synapse string 12, a second synapse string 14, and a device isolation portion 16. The channel hole 110 has a pillar shape extending in a vertical direction and is filled with an insulating material. The three-dimensional stackable synapse string 1 may be provided on a substrate. The first synapse string 12 may be provided on the first surface of the outer peripheral surface of the channel hole, and include a plurality of first synapse devices stacked along a vertical direction of the channel hole. The second synapse string 14 may be provided on the second surface of the outer peripheral surface of the channel hole, and may include a plurality of second synapse devices stacked along the vertical direction of the channel hole. The device isolation portion 16 may be provided on the outer peripheral surface of the channel hole between the first synapse string and the second synapse string. Accordingly, the three-dimensional stackable synapse string of the present invention may be configured to include two synapse strings electrically separated from each other by the device isolation portion 16 on the outer peripheral surface of the channel hole 110.

Each of the first synapse devices of the first synapse string 12 comprises a first semiconductor body (Body 1) 120, a first word line (WL1) 160, and a first insulator stack 170. A plurality of first insulating layers (Oxide1) 130 are provided between the first synapse devices, respectively. The first synapse string 12 further includes a first upper electrode (DL) 140, and a first lower electrode (SL) 150. In the first synapse string 12 having the above configuration, the first semiconductor body 120, the first insulator stack 170, and the first word line 160 positioned on the same layer on the first side of the channel hole may constitute the first synapse device or a part thereof. The first synapse devices are isolated from each other by the first insulating layers 130 and are electrically connected in series by the first semiconductor body 120. The first upper electrode 140 and the first lower electrode 150 are provided at opposite ends of the first synapse string 12, respectively. Accordingly, the first synapse devices and the first insulating layers 130 are alternately arranged on the first side of the channel hole to form the first synapse string 12.

Each of the second synapse devices of the second synapse string 14 comprises a second semiconductor body (Body 2) 122, a second word line (WL2) 162, a second insulator stack 172. A plurality of second insulating layers (Oxide 2) 132 are provided between the second synapse devices, respectively. The second synapse string 14 further includes a second upper electrode and a second lower electrode. In the second synapse string 14 having the above configuration, the second semiconductor body 122, the second insulator stack 172, and the second word line 162 positioned on the same layer on the second side of the channel hole may constitute the second synapse device or a part thereof. The second synapse devices are isolated from each other by the second insulating layers 132 and are electrically connected in series by the second semiconductor body 122. The second upper electrode and second lower electrode are provided at opposite ends of the second synapse string 14, respectively. The second upper electrode may be shared with the first upper electrode 140, and the second lower electrode may be shared with the first lower electrode 150. Accordingly, the second synapse devices and the second insulating layers are alternately arranged on the second side of the channel hole to form the second synapse string 14.

The device isolation portion 16 comprises a third semiconductor body 124, a plurality of third insulating layers 134, and a plurality of fourth insulating layers 136. The device isolation portion 16 may be configured to electrically isolate the first synapse string 12 from the second synapse string 14. The third semiconductor body 124 may be provided in a thin-film form between the first surface and the second surface on the outer peripheral surface of the channel hole. A plurality of the third insulating layers 134 are arranged along a vertical direction on the outer peripheral surface of the third semiconductor body. A plurality of the fourth insulating layers 136 are arranged along the vertical direction on the outer peripheral surface of the third semiconductor body 124 and alternately stacked with the third insulating layers 134.

Hereinafter, each of the above-described components will be described in detail.

The upper surface of the substrate may be made of an oxide layer 100, and the three-dimensional stackable synapse string according to the present invention may be provided along the vertical direction on the oxide layer 100 of the substrate.

The channel hole 110 may be located above the oxide layer 100 on the upper surface of the substrate, provided in a pillar shape along a direction perpendicular to the surface of the substrate, and filled with an oxide material having electrical insulation properties.

The first semiconductor body 120, the second semiconductor body 122, and the third semiconductor body 124 are positioned on the surface of the channel hole, and are provided by applying a semiconductor material to the surface of the channel hole in the form of a thin layer. The first semiconductor body 120, the second semiconductor body 122, and the third semiconductor body 124 may be made of a semiconductor material such as polysilicon, poly-SiGe, metal oxide, or the like. The first and second semiconductor bodies having the above-described structure are configured to form a channel during device operation. The first, second, and third semiconductor bodies may be made the same structure and material. The first semiconductor body 120 and the second semiconductor body 122 can be connected to each other with the third semiconductor body 124 interposed therebetween.

The first insulating layers 130 are positioned on the outer circumferential surface of the first semiconductor body 120, are spaced apart from each other along the outer circumferential surface of the first semiconductor body 120, and are vertically stacked. The first insulating layers 130 may be formed of, for example, an oxide layer. The first insulating layers 130 can electrically insulate the first synapse devices from each other. The second insulating layers 132 are positioned on the outer circumferential surface of the second semiconductor body 122, are spaced apart from each other along the outer circumferential surface of the second semiconductor body 122, and are vertically stacked. The second insulating layers 132 may be formed of, for example, an oxide layer. The second insulating layers electrically insulate the second synapse devices from each other. The first insulating layer 130, the second insulating layer 132, and the third insulating layer 134 may be formed of the same material and be connected to each other.

The first word lines 160 are positioned on the outer circumferential surface of the first semiconductor body 120, and are alternately stacked with first insulating layers 130. The first insulator stacks 170 are provided between at least the first word lines 160 and the first semiconductor body 120, respectively, and may be further provided between the first word lines 160 and the first insulating layers 130, respectively. The first insulator stack 170 may be composed of a single layer or a stack structure in which at least two or more layers are stacked, and include a layer that stores electric charges or causes polarization.

The second word lines 162 are positioned on the outer circumferential surface of the second semiconductor body 122, and are alternately stacked with second insulating layers 132. The second insulator stacks 172 are provided between at least the second word lines 162 and the second semiconductor body 122, respectively, and may be further provided between the second word lines 162 and the second insulating layers 132, respectively. The second insulator stack 172 may be composed of a single layer or a stack structure in which at least two or more layers are stacked, and include a layer that stores electric charges or causes polarization.

When the first insulator stack 170 and the second insulator stack 172 may be composed of a single layer, respectively, it may be formed of an oxide layer, a nitride layer, or the like. And, when the first insulator stack 170 and the second insulator stack 172 may be configured in a stack structure, respectively, it may include at least a charge storage layer and an insulating layer, at least a ferroelectric layer and an insulating layer, at least a resistance change layer and an insulating layer, or at least a phase change layer and an insulating layer.

The first insulator stack 170 and the second insulator stack 172 preferably have a stack structure in which a plurality of layers including at least a charge storage layer and an insulating layer are stacked, and the structure of the insulator stacks may be implemented in various embodiments. On the other hand, when the first insulator stack 170 and the second insulator stack 172 include a charge storage layer and an insulating layer, preferably no insulating layer or an insulating layer with a thickness of 4 nm or less is disposed between the semiconductor body and the charge storage layer, so that the operating voltage can be lowered.

In addition, the first insulator stack 170 and the second insulator stack 172 may be configured by stacking a plurality of insulating layers. In this case, at least one of the insulating layers constituting the insulator stack includes an insulating layer having a trap for enabling charge storage, and the insulating layer operates as a charge storage layer, so that the device can implement a memory function for storing information in a non-volatile form. For example, the insulator stacks may be formed in a stacked structure of a first insulating layer, a charge storage layer, and a second insulating layer, or may be formed in a stacked structure of an insulating layer and a charge storage layer. Here, the insulating layer of the insulator stacks may use silicon oxide, aluminum oxide, etc., and the charge storage layer may use silicon nitride, hafnium oxide, or the like.

In addition, at least one of the insulating layers constituting the first insulator stack 170 and the second insulator stack 172 may implement a memory function for storing information in a non-volatile form using a polarization-inducing material. For example, the insulator stacks may be formed in a stacked structure of a material layer causing polarization and an insulating layer. Here, the insulating layer of the insulator stacks may be formed of silicon oxide, aluminum oxide, or the like, and a plurality of materials including hafnium oxide (HfZrOₓ) may be used as the polarization-inducing material.

The device isolation portion 16 includes a plurality of third insulating layers 134 and a plurality of fourth insulating layers 136 alternately stacked to provide electrical isolation between the first synapse string 12 and the second synapse string 14. The third and fourth insulating layers 132 & 136 are provided on the outer peripheral surface of the third semiconductor body 124. The third insulating layers 134 may be, for example, an oxide layer. The fourth insulating layers 136 may be alternately stacked with third insulating layers 134, and may be, for example, a nitride layer. The first insulating layer 130, the second insulating layer 132, and the third insulating layer 134 may be formed of the same material and be connected to each other.

Referring to FIGS. 2 and 3, the first word lines 160 and first insulating layers 130 are alternately stacked on the first side surface of the channel hole 110 in the first direction. The second word lines 162 and the second insulating layers 132 are alternately stacked on the second side surface of the channel hole 110 in the first direction. In addition, the third insulating layers 134 and the fourth insulating layers 136 are alternately stacked on the outer peripheral surface of the third semiconductor body 124 between the first synapse string 12 and the second synapse string 14. The first upper electrode 140 is disposed on the channel hole 110 and is electrically connected to the first end of the first semiconductor body 120. The second upper electrode is disposed on the channel hole and is electrically connected to the first end of the second semiconductor body. The first lower electrode 150 is disposed under the channel hole 110 and is electrically connected to the second end of the first semiconductor body 120. The second lower electrode is disposed under the channel hole and is electrically connected to the second end of the second semiconductor body. The first and second upper electrodes and the first and second lower electrodes are made of a material having electrical conductivity, and for example, may be made of one of various metals, silicides, or semiconductor materials doped with impurities. The semiconductor material may include an amorphous semiconductor, a single crystal semiconductor, a polycrystalline semiconductor, and the like. The first upper electrode 140 may be shared with the second upper electrode and the first lower electrode 150 may be shared with the second lower electrode.

The second synapse string 14 may have the same structure of the first synapse string 12 on the second side opposite to the first side of the channel hole, thereby further improving the degree of integration. The second synapse string 14 includes a plurality of second word lines 162 and a plurality of second insulator stacks 172, and may be configured to share the first upper electrode 140 and the first lower electrode 150 of the first synapse string 12. Here, the second synapse device has the same structure as the first synapse device, the second word line 162 has the same structure as the first word line 160, and the second insulator stack 172 has the same structure as the first insulator stack 170. In FIG. 3A, the first side surface of the channel hole 110 may correspond to a left side of the channel hole 110, and the second side surface opposite to the first side surface may correspond to a right side of the channel hole 110. The device isolation portion 16 may be comprised the fourth insulating layers 136 and the third insulating layers 134 disposed on the surface of the third semiconductor body 124. Therefore, the device isolation portion 16 can isolate the first synapse string 12 from the second synapse string 14.

Accordingly, the first synapse string 12 and the second synapse string 14 may share the first upper electrode and the second upper electrode, and may share the first lower electrode and the second lower electrode. The present invention can provide a basic synapse device or a part thereof that can be effectively implemented in a three-dimensional string structure, and can improve the degree of integration and the performance of the device by the above-described structure. And, the three-dimensional stackable synapse string having the above-described structure can be applied to various array architectures, and preferably can be applied to NAND device-type Synapse Array Architecture.

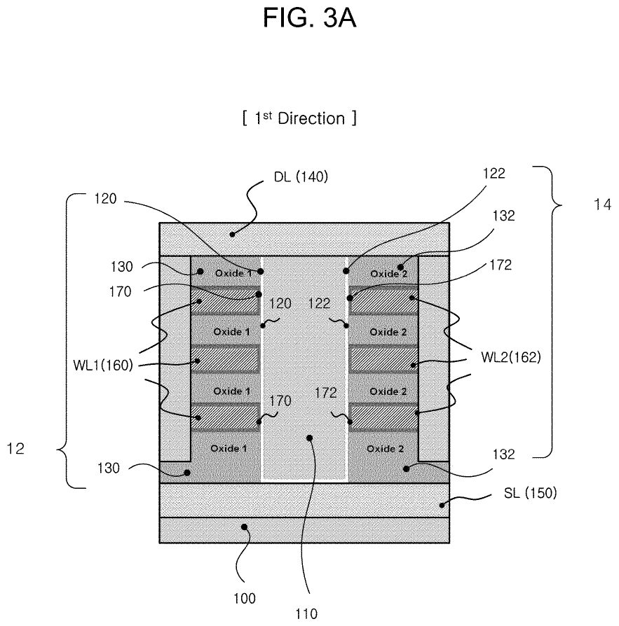

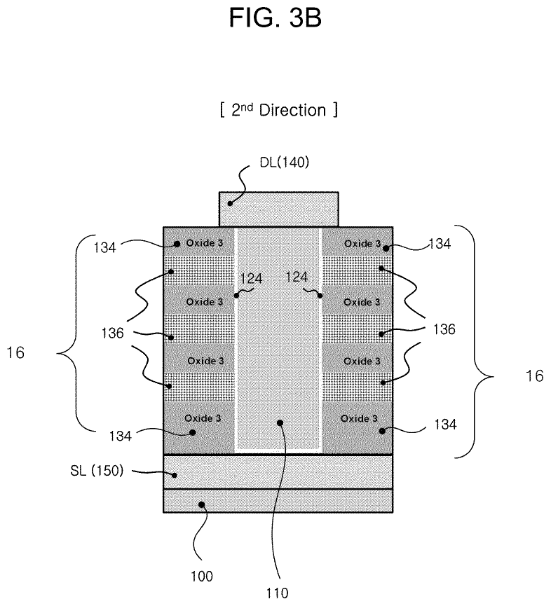

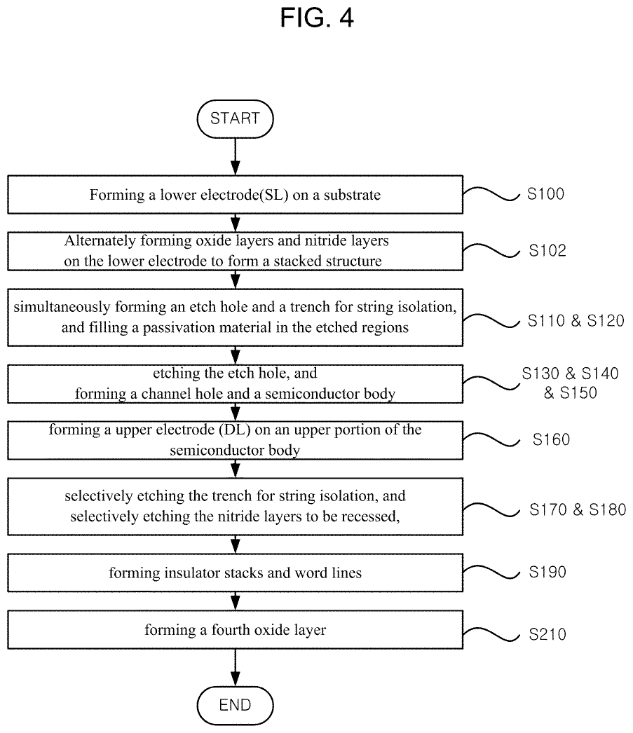

Hereinafter, with reference to FIGS. 4 and 5, a method for manufacturing the above-described three-dimensional stackable synapse string will be described in detail.

FIG. 4 is a flowchart sequentially illustrating a method for manufacturing the three-dimensional stackable synapse string according to the preferred embodiment of the present invention shown in FIGS. 3A and 3B, and FIGS. 5A and 5B are cross-sectional views and top views showing the results of each step of FIG. 4.

Referring to FIGS. 4 and 5A and 5B, first, an oxide layer is formed on a substrate, a thin layer made of a semiconductor material doped with N+ is formed thereon in a first direction, and then patterned through a photolithography process to form a lower electrode (step 100, (a) of FIG. 5A). Here, polysilicon may be used as the semiconductor material. Then, an oxide layer is formed on the resultant having the lower electrode and then planarized the surface ((b) of FIG. 5A).

Next, a stacked structure is formed by alternately and repeatedly forming oxide layers and nitride layers on the planarized surface (step 102, (c) of FIG. 5A). Here, the oxide layers will constitute the first insulating layers, the second insulating layers, and the third insulating layers, and the nitride layers will be the fourth insulating layers.

Preferably, the oxide layers and the nitride layers are made of materials having different etch ratios, so that while the oxide layers are etched, the nitride layers are hardly etched, and while the nitride layers are etched, the oxide layers are hardly etched. Here, an oxide layer may be used as the first, second and third insulating layers, and a nitride layer may be used as the fourth insulating layers. Then, predetermined regions of the stacked structure are etched using a photolithography process to simultaneously form an etch hole and a trench isolation for strings (step 110, (d) of FIG. 5A). Then, after depositing a passivation material on the etched regions of the stack structure, the surface is planarized (step 120, (e) of FIG. 5A). The passivation material may be polysilicon. Then, a channel hole is formed by selectively etching the passivation material filled in the etching hole to expose the etching hole (step 130, (f) of FIG. 5A).

Next, a semiconductor body made of a semiconductor material to be used as a channel is formed on the surface of the channel hole (step 140, (g) of FIG. 5A). The channel hole in which the semiconductor body is formed may be filled with an oxide material and planarized the surface (step 150, (h) of FIG. 5A). Then, an upper electrode is formed on the semiconductor body (step 160, (i) of FIG. 5B).

Next, a passivation material of the trench for string isolation is selectively etched to expose the trench for string isolation (step 170, (j) of FIG. 5B). Then, after selectively etching the fourth insulating layers from the exposed surface of the trench for string isolation (step 180, (k) of FIG. 5B), insulator stacks are formed on the surfaces of the recessed spaces, and a conductive material are formed and isotropically etched to form a plurality of word lines separated by layers (step 190, (l) of FIG. 5B).

Next, the trench for string isolation may be filled with an oxide material and then planarized the surface (step 210, (m) of FIG. 5B). Through the above-described manufacturing process, a three-dimensional stackable synapse string according to a preferred embodiment of the present invention is completed.

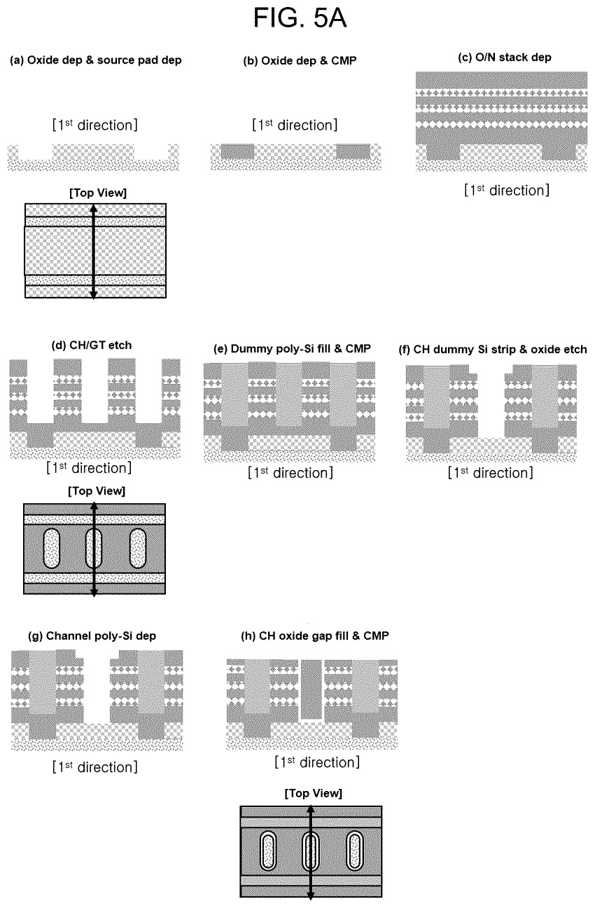

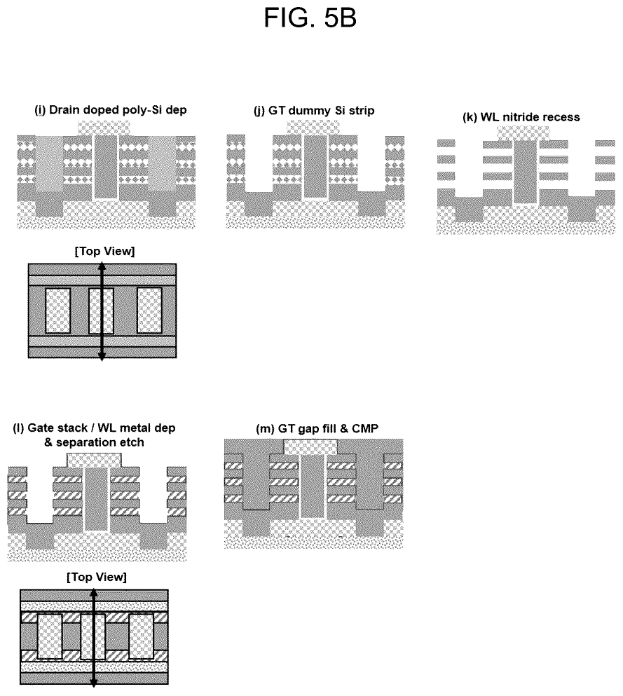

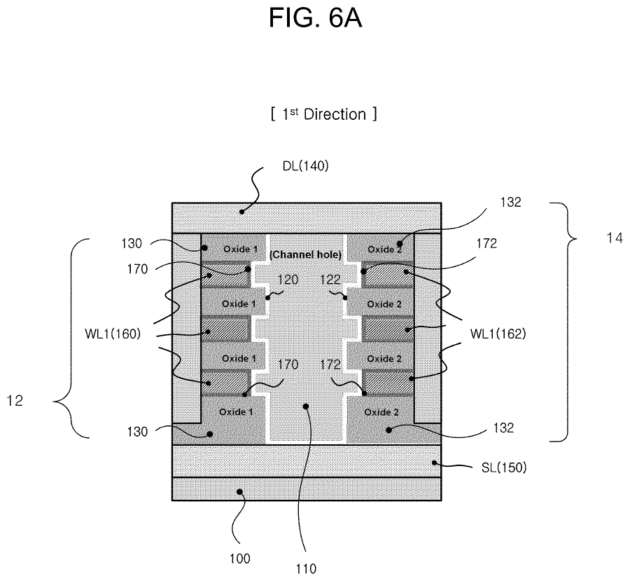

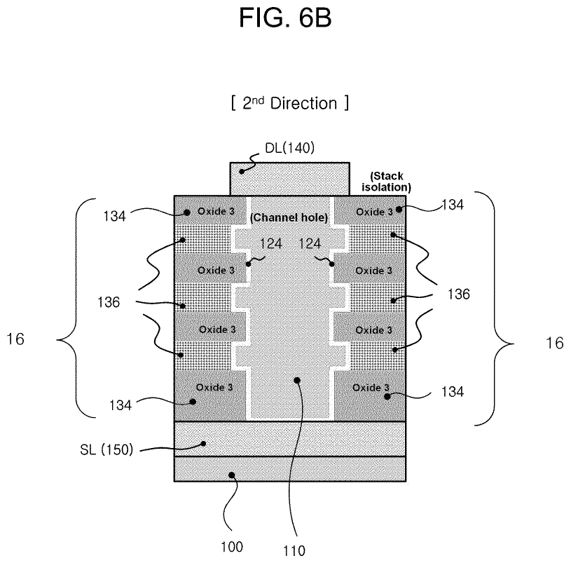

FIGS. 6A and 6B are cross-sectional views in first and second directions illustrating another embodiment of a channel hole in the three-dimensional stackable synapse string according to the preferred embodiment of the present invention.

Referring to FIGS. 6A and 6B, the regions in which the synapse devices are formed among the surface of the channel hole protrude toward the word lines and extend. And, as the semiconductor body is provided on the surface of the channel hole, the semiconductor body is formed as a thin layer in a zigzag shape in a vertical direction.

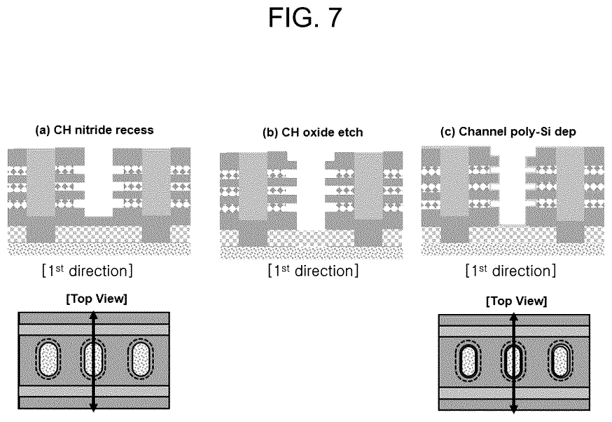

FIG. 7 is cross-sectional views and top views showing the results of some steps in the manufacturing method of the three-dimensional stackable synapse string of the present invention shown in FIGS. 6A and 6B.

Referring to FIG. 7, the manufacturing method of the three-dimensional stackable synapse string according to the present embodiment is basically the same as the process described in FIGS. 4 and 5A and 5B, except that after the step of forming the channel hole (step 130) by selectively etching the passivation material filled in the etch hole, the following processes are further provided. The fourth insulating layers are partially etched from the surface of the channel hole to be partially recessed (step 132, (a) of FIG. 7), and the third insulating layers are etched from the surface of the channel hole to expose the surface of the lower electrode (step 134, (b) of FIG. 7), and a semiconductor body made of polysilicon to be used as a channel is formed on the surface of the channel hole (step 136, (c) of FIG. 7). In this way, by further comprising the steps 132 to 136 described above, the surface of the channel hole where the synapse devices are to be formed may be protruded.

Hereinafter, with reference to the accompanying drawings, in the three-dimensional stackable synapse string according to the preferred embodiment of the present invention, another embodiment of the lower electrode will be described.

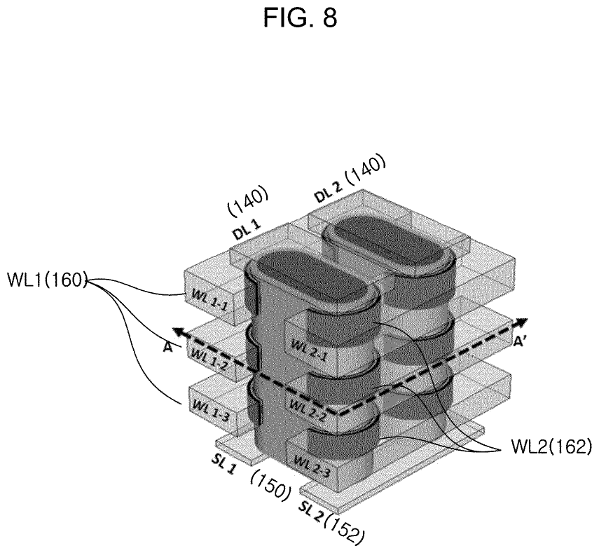

FIG. 8 is a perspective view showing another embodiment of a lower electrode in the three-dimensional stackable synapse string according to the preferred embodiment of the present invention, FIG. 9 is a cross-sectional view taken along the A-A direction of FIG. 8, FIG. 10A is a cross-sectional view taken in the first direction of FIG. 9, and FIG. 10B is a cross-sectional view taken in the second direction of FIG. 9.

Referring to FIGS. 8 to 10, the first synapse string and the second synapse string provided on both sides of one channel hole include the first lower electrode 150 and the second lower electrode 152 separated from each other, respectively.

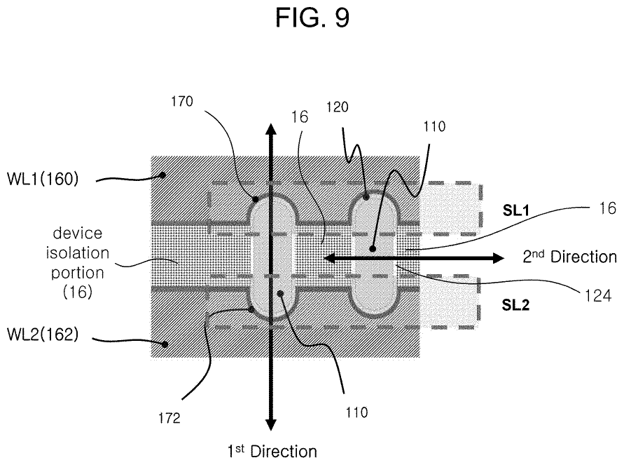

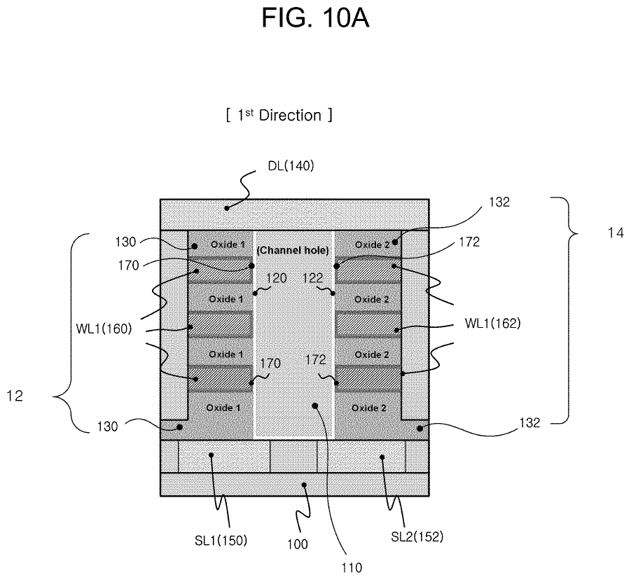

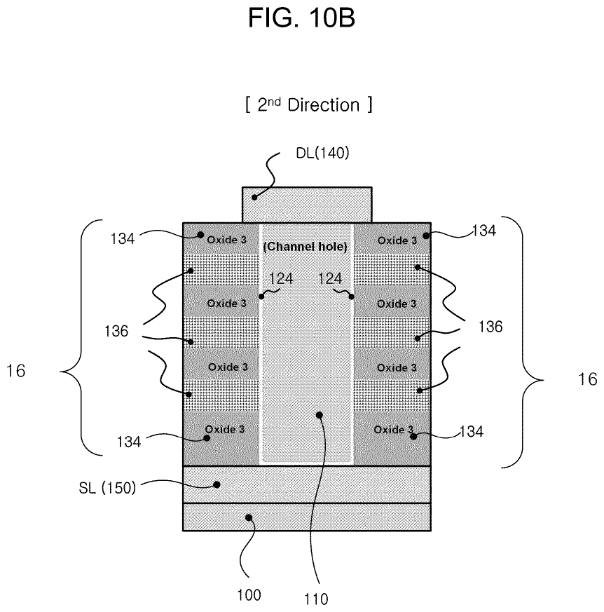

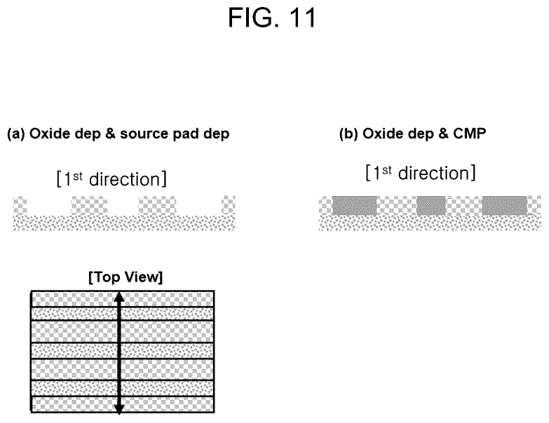

FIG. 11 is cross-sectional views and top views showing the results of some steps in the manufacturing method of the three-dimensional stackable synapse string of the present invention shown in FIG. 8.

Referring to FIG. 11, the manufacturing method of the three-dimensional stackable synapse string according to the present embodiment is basically the same as the process described in FIGS. 4 and 5, and in the step of forming the first lower electrode and the second lower electrode on the substrate, the first and the second lower electrodes separated from each other in one channel hole are patterned and provided.

### 3D Stackable Synapse Array

The three-dimensional stackable synapse array according to the present invention may be configured by sequentially arranging the three-dimensional stackable synapse string having the above-described structure. In addition, a NAND-type synapse array can be configured by arranging three-dimensional stackable synapse strings.

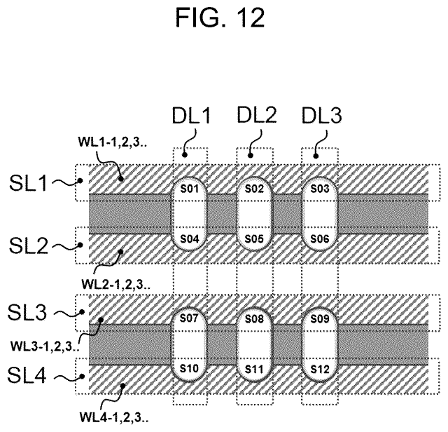

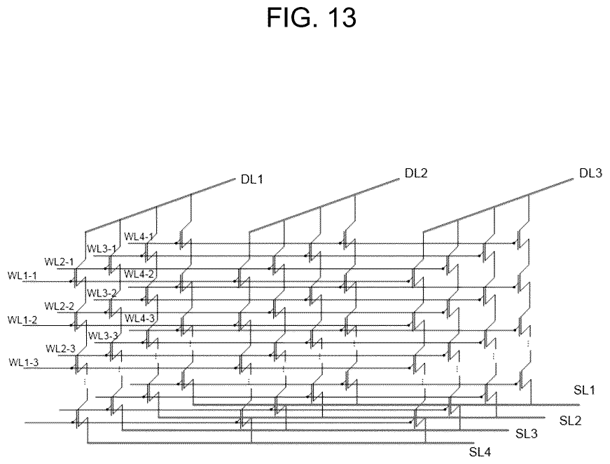

FIGS. 12 and 13 are a cross-sectional view and an equivalent circuit diagram illustrating an example of a NAND-type synapse array structure configured using three-dimensional stackable synapse arrays using the three-dimensional stackable synapse string according to the present invention.

Referring to FIGS. 12 and 13, in the NAND-type synapse array according to the present invention, the upper electrodes (DL1, DL2, DL3) and the lower electrodes (SL1, SL2,SL3, SL4) connected to each synapse string are disposed in a direction perpendicular to each other, and the stacked string structures are repeatedly arranged so that word lines are arranged.

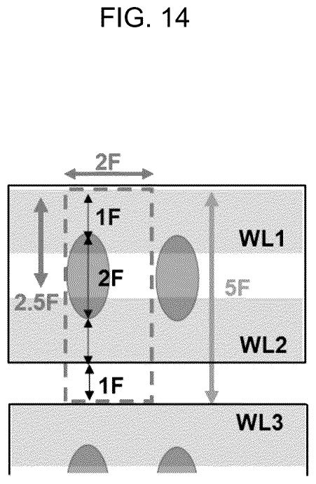

FIG. 14 is a schematic diagram illustrating the degree of integration in the three-dimensional stackable synapse string according to the present invention.

When the size of one cell in the structure according to the present invention is calculated with reference to FIG. 14, since two strings occupy the stack width (4F)+isolation (1F) in the first direction and the spacing between cells (2F) in the second direction, the area effectively occupied by one string becomes 5F².

### Selective Program and Erase Operations

Hereinafter, in the three-dimensional stackable synapse array according to the present invention, selective program and selective erase operations for a target device will be described with reference to the accompanying drawings.

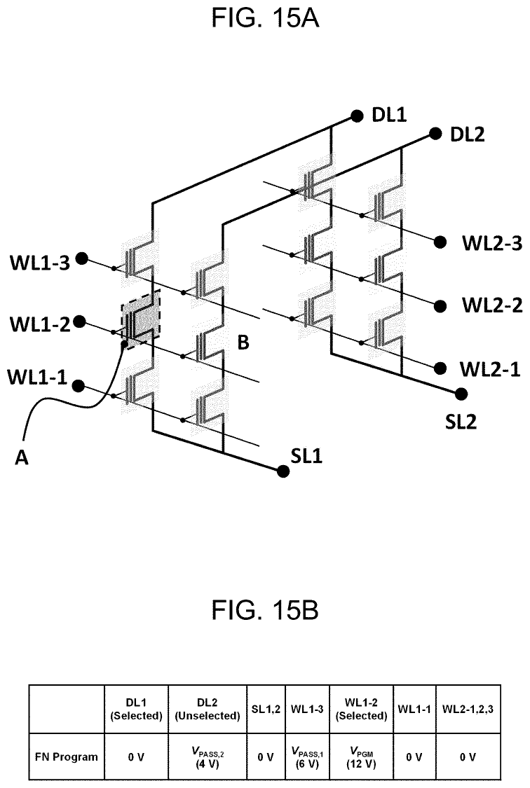

FIGS. 15A and 15B are an equivalent circuit diagram and a table showing voltages applied to each terminal for explaining a selective program operation for a target device in the three-dimensional stackable synapse array according to the present invention.

The three-dimensional stackable synapse array shown in FIG. 15 is a three-dimensional stackable synapse array structure in which three layers are vertically stacked and two pairs of devices are horizontally provided, and it consists of 6 WLs and two SLs and DLs, and is a NAND type synapse array.

Referring to FIGS. 15A and 15B, first, a preset program voltage V_{PGM} is applied to the WL of a layer to be programmed, and 0 V is applied to the upper electrode (DL) and the lower electrode (SL) connected to the WL, respectively, so that electrons are injected using the F-N tunneling mechanism. At this time, a preset first pass voltage (Vpass 1) is applied to WL1-3 of the layer between the target device and the upper electrode, 0 V is applied to WLs of another adjacent layers, and a preset lower pass voltage (Vpass 2) is applied to another adjacent DLs to block the program operation. Here, V_{PGM} is a positive voltage large enough to cause F-N tunneling in the first insulator stack that separates the WL line and the body region. In addition, Vpass 1 is a positive voltage enough to form a channel by turning on all devices of other adjacent layers of the same string. Vpass 2 is a positive voltage enough to reduce the voltage difference with V_{PGM} so that F-N tunneling does not occur in neighboring cells sharing WL with the target cell. It is generally desirable to have half the V_{PGM} value. A voltage of Vpass 1 is applied to WLs of other layers adjacent to the target cell to transmit the voltage of the upper electrode to all channels.

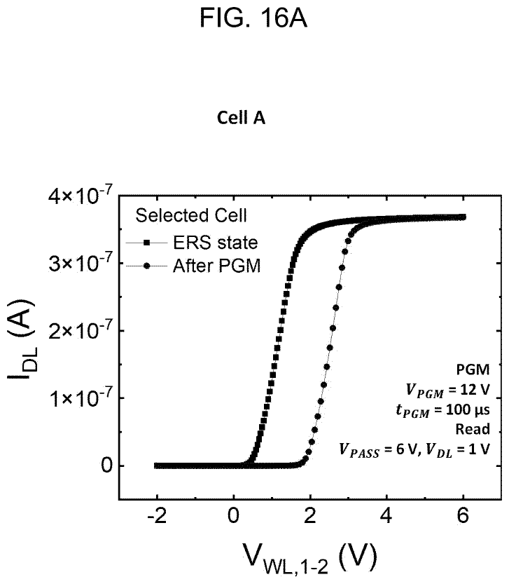

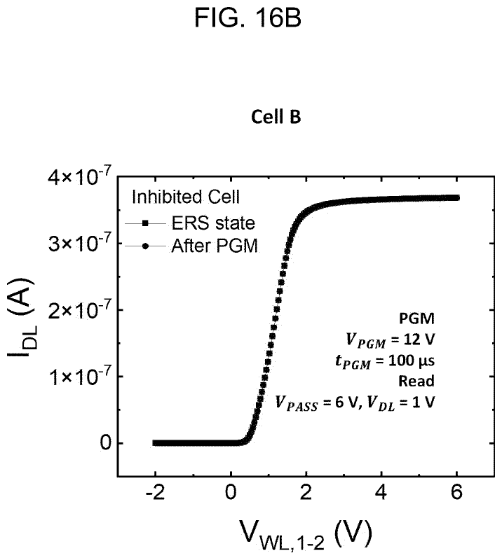

FIGS. 16A and 16B are graphs of read results for a synapse device (CELL A) that has performed a program operation and a synapse device (CELL B) that does not perform a program operation according to the selective write operation according to FIGS. 15A and 15B.

FIGS. 16A and 16B are a result of measuring the current flowing in DL1 by applying a turn-on voltage to WL of the target cell after electrons are injected into the target cell under the above-described conditions of FIGS. 15A and 15B.

FIG. 16A is a graph of a read result for CELL A, which is a device on which a selective program operation has been performed. The left line is the current in the initial state, and the right line is the current after the selective program operation. Referring to FIG. 16A, it can be seen that the current flowing through CELL A is decreased from the initial state and changed after the selective program operation. Meanwhile, FIG. 16B is a graph of a read result for CELL B, which is a device on which a program operation is not performed. Referring to FIG. 16B, it can be confirmed that the current flowing through CELL B after the selective program operation on CELL A is the same as the initial state. That is, since FN tunneling does not occur in CELL A's neighbor CELL B, the graph hardly changes.

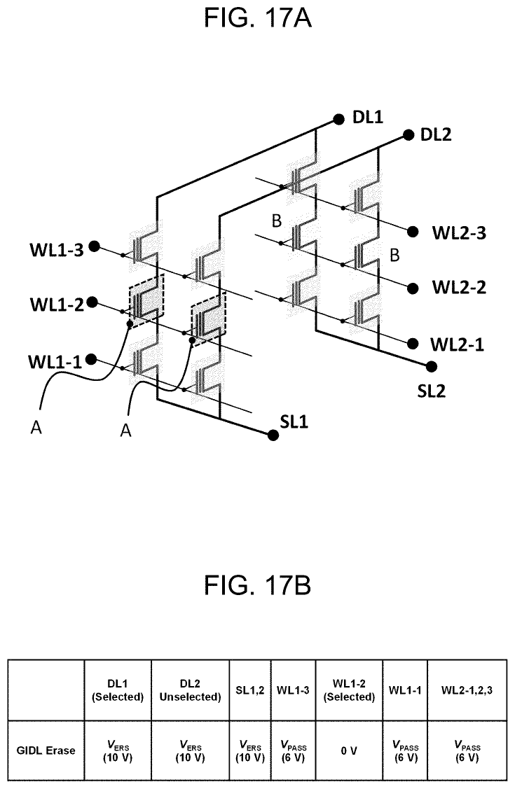

FIGS. 17A and 17B are an equivalent circuit diagram and a table showing voltages applied to each terminal for explaining a selective erase operation for a target device in the three-dimensional stackable synapse array structure shown in FIGS. 16A and 16B.

Referring to FIGS. 17A and 17B, in the structure according to the present invention, holes are generated using a hot-hole injection (HHI) mechanism. In the structure according to the present invention, the erase operation occurs simultaneously in the synapse devices sharing the same WL. A preset erase voltage (V_{ERS}) is applied to all DLs and SLs, and Vpass is applied to WLs adjacent to the target WL, WL1-3 and WL1-1, to generate and inject holes by GIDL. 0V is applied to the target WL to inject holes into the charge storage layer. At this time, Vpass is applied to the WLs of the other layer to prevent hole injection. Here, V_{ERS} is a positive voltage large enough to generate holes by a gate induced drain leakage (GIDL) current between the WL line and the DL line and inject the holes into the insulator stack.

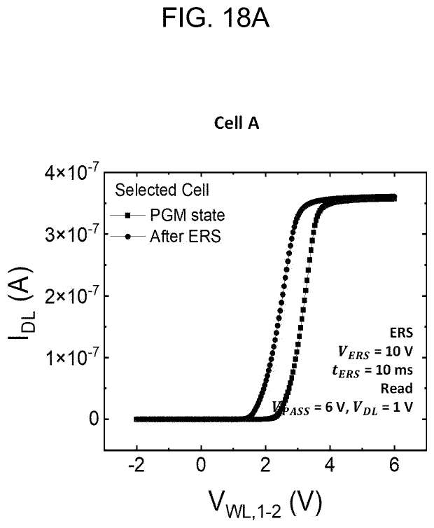

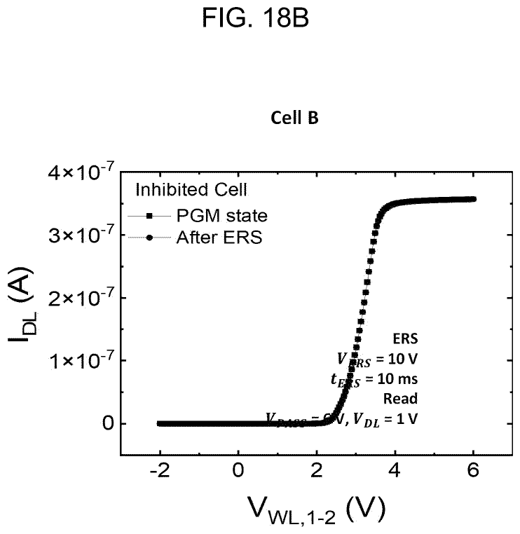

FIGS. 18A and 18B are graphs of read results for a synapse device (CELL A) that has performed a selective program operation and a synapse device (CELL B) that does not perform a selective program operation according to the selective program operation according to FIGS. 17A and 17B.

FIGS. 18A and 18B are results of measuring the current flowing in DL1 by applying a turn-on voltage to WL of the target cell after injecting holes into the target cell under the above-described condition of FIGS. 17A and 17B.

FIG. 18A is a graph of a read result for CELL A, which is a device subjected to an erase operation. The right line is the current in the initial state, and the left line is the current after the selective program operation. Referring to FIG. 18A, it can be seen that the current flowing through CELL A increases and changes from the initial state after the erase operation. Meanwhile, referring to FIG. 18B, it can be confirmed that the current flowing through CELL B after the selective erase operation on CELL A is the same as the initial state. That is, the HHI mechanism does not occur in CELL B adjacent to CELL A, so that the graph hardly changes.

In the above, the present invention has been described with respect to the preferred embodiment thereof, but this is only an example and does not limit the present invention. It will be appreciated that various modifications and applications not exemplified above are possible within the scope. And, the differences related to such modifications and applications should be construed as being included in the scope of the present invention defined in the appended claims.

What is claimed is:

1. A three-dimensional stackable synapse string, comprising:
a channel hole having a pillar shape extending in a vertical direction and being filled with an insulating material;
a first synapse string provided on a first surface of an outer peripheral surface of the channel hole, the first synapse string including a plurality of first synapse devices stacked along a vertical direction of the channel hole;
a second synapse string provided on a second surface of the outer peripheral surface of the channel hole, the second synapse string including a plurality of second synapse devices stacked along the vertical direction of the channel hole; and
a device isolation portion provided on the outer peripheral surface of the channel hole between the first and the second synapse strings,
wherein the three-dimensional stackable synapse string is configured to include two synapse strings electrically separated from each other by the device isolation portion on the outer peripheral surface of the single channel hole.

2. The three-dimensional stackable synapse string according to claim 1, wherein each of the first synapse devices of the first synapse string comprises:
a first semiconductor body provided in a thin-film form on the first surface of the outer peripheral surface of the channel hole;
a first word line positioned on an outer peripheral surface of the first semiconductor body; and
a first insulator stack positioned between the first word line and the first semiconductor body,
wherein the first word lines of the first synapse string are electrically separated from each other, and the first synapse devices are electrically connected to each other by the first semiconductor body to form the first synapse string, and
wherein each of the second synapse devices of the second synapse string comprises:
a second semiconductor body provided in a thin-film form on the second surface of the outer peripheral surface of the channel hole;
a second word line positioned on an outer peripheral surface of the second semiconductor body; and
a second insulator stack positioned between the second word line and the second semiconductor body,
wherein the second word lines of the second synapse string are electrically separated from each other, and the second synapse devices are electrically connected to each other by the second semiconductor body to form the second synapse string.

3. The three-dimensional stackable synapse string according to claim 1, wherein the device isolation portion comprises:
a third semiconductor body provided in a thin-film form between the first surface and the second surface on the outer peripheral surface of the channel hole;
a plurality of third insulating layers arranged along a vertical direction on an outer peripheral surface of the third semiconductor body; and
a plurality of fourth insulating layers arranged along the vertical direction on the outer peripheral surface of the third semiconductor body and alternately stacked with the third insulating layers,
wherein the device isolation portion electrically isolates the first synapse string from the second synapse string.

4. The three-dimensional stackable synapse string according to claim 3, wherein the first, second, and third semiconductor bodies have the same structure and are made of the same material.

5. The three-dimensional stackable synapse string according to claim 4, wherein the first and the second semiconductor bodies are connected to each other with the third semiconductor body interposed therebetween.

6. The three-dimensional stackable synapse string according to claim 1, wherein regions of the surface of the channel hole on which the first synapse devices and the second synapse devices are provided protrude toward the first word lines and the second word lines, respectively.

7. The three-dimensional stackable synapse string according to claim 2, wherein the first insulator stack and the second insulator stack are each configured as a single insulating layer or as a stack structure including a plurality of stacked layers, and
wherein, in the stack structure, each of the first insulator stack and the second insulator stack includes at least a charge storage layer and an insulating layer, or at least a ferroelectric layer and an insulating layer, or at least a resistive switching layer and an insulating layer, or at least a phase change layer and an insulating layer.

8. The three-dimensional stackable synapse string according to claim 2, wherein the first insulator stack and the second insulator stack have the same structure and are made of the same material.

9. The three-dimensional stackable synapse string according to claim 1, further comprising:
a first upper electrode disposed above the channel hole and electrically connected to a first end of the first synapse string;
a first lower electrode disposed below the channel hole and electrically connected to a second end of the first synapse string;
a second upper electrode disposed above the channel hole and electrically connected to a first end of the second synapse string; and
a second lower electrode disposed below the channel hole and electrically connected to a second end of the second synapse string.

10. The three-dimensional stackable synapse string according to claim 9, wherein the first synapse string and the second synapse string share the first upper electrode and the second upper electrode with each other, and share the first lower electrode and the second lower electrode with each other.

11. The three-dimensional stackable synapse string according to claim 9, wherein the first synapse string and the second synapse string share the first upper electrode and the second upper electrode, and do not share the first lower electrode and the second lower electrode.

12. The three-dimensional stackable synapse string according to claim 9, wherein the three-dimensional stackable synapse string is provided on a substrate having an oxide layer on a surface thereof,
wherein the first lower electrode is disposed between the second end of the first synapse string and an upper surface of the oxide layer of the substrate, and
wherein the second lower electrode is disposed between the second end of the second synapse string and the upper surface of the oxide layer of the substrate.

13. A three-dimensional stackable synapse array comprising a plurality of the three-dimensional stackable synapse strings according to claim 1,
wherein the three-dimensional stackable synapse strings are arranged in an array form.

14. The three-dimensional stackable synapse array of claim 13, further comprising a CMOS integrated circuit used as a peripheral circuit below a substrate.
